(19) United States
(12) Patent Application Publication
(10) Pub. No.: US 2026/0319071 A1
(43) Pub. Date: Oct. 15, 2026

(54) OPTOELECTRONIC ARRANGEMENT AND METHOD FOR PRODUCING AN OPTOELECTRONIC ARRANGEMENT

(71) Applicant: ams-OSRAM International GmbH, Regensburg (DE)

(72) Inventors: Jörn KAMPMEIER, Obertraubling (DE); Wolfgang NEUMANN, Regensburg (DE); Fabian KNORR, Postbauer-Heng (DE)

(73) Assignee: ams-OSRAM International GmbH, Regensburg (DE)

(21) Appl. No.: 19/113,672

(22) PCT Filed: Sep. 14, 2023
(86) PCT No.: PCT/EP2023/075227

§ 371 Date: Mar. 20, 2025

(30) Foreign Application Priority Data
Sep. 23, 2022 (DE) 10 2022 124 500.4

(51) Int. Cl. G01S 7/481

(52) U.S. Cl. CPC G01S 7/4815

(57) ABSTRACT

The invention relates to an optoelectronic arrangement. The optoelectronic arrangement includes a semiconductor body configured to emit coherent electromagnetic radiation in a main emission direction, an optical deflection element, and an evaluation unit. The optical deflection element is disposed downstream of the semiconductor body in the main emission direction thereof. The optical deflection element fans out the electromagnetic radiation over a lateral emission angle in a lateral direction and over a vertical emission angle in a vertical direction. The evaluation unit is configured to detect the electromagnetic radiation from the semiconductor body reflected by an object. The invention also relates to a method for producing an optoelectronic arrangement.

### CROSS-REFERENCE TO RELATED APPLICATIONS

The present application is a national stage entry from International Application No. PCT/EP2023/075227, filed on Sep. 14, 2023, published as International Publication No. WO 2024/061717 A1 on Mar. 28, 2024, and claims priority to German Patent Application No. 10 2022 124 500.4, filed Sep. 23, 2022, the disclosures of all of which are hereby incorporated by reference in their entireties.

### FIELD

An optoelectronic arrangement and a method for producing an optoelectronic arrangement are disclosed. The optoelectronic arrangement is configured in particular for generating and/or detecting electromagnetic radiation, for example light perceptible to the human eye.

### BACKGROUND

One task to be solved is to specify an optoelectronic arrangement that enables a two-or three-dimensional surface to be detected.

A further task to be solved is to specify a method for producing an optoelectronic arrangement which enables a two-or three-dimensional surface to be detected.

These tasks are solved by the device and the method according to the independent patent claims. Advantageous embodiments and further embodiments of the device and the method are the subject of the dependent patent claims and are further apparent from the following description and the figures.

### SUMMARY

According to at least one embodiment, the optoelectronic arrangement comprises a semiconductor body configured to emit coherent electromagnetic radiation in a main emission direction. In particular, the semiconductor body comprises an optically active region, which is configured to emit electromagnetic radiation. Preferably, the optically active region has a p-n junction, a double heterostructure, a single quantum well (SQW) structure or a multi-quantum well (MQW) structure for the generation of radiation. The semiconductor body is, for example, a luminescence diode, in particular a laser diode.

The semiconductor body preferably emits electromagnetic radiation in the infrared spectral range. For example, the spectral range of the electromagnetic radiation emitted by the semiconductor body during operation has a half-width FWHM between 10 nm and 15 nm.

In particular, an optical resonator is formed in the semiconductor body along a resonator axis. The optical resonator enables a circulation of electromagnetic radiation along the resonator axis and favors a stimulated emission of electromagnetic radiation. Advantageously, the optical resonator enables coherent emission of electromagnetic radiation. For example, the resonator axis determines the main emission direction of the semiconductor body. In other words, the main emission direction is parallel and in particular coaxial to the resonator axis.

According to at least one embodiment, the optoelectronic arrangement comprises an optical deflection element. In particular, the optical deflection element is configured to change a propagation direction of an electromagnetic radiation. Preferably, the optical deflection element is used to radiate electromagnetic radiation into a predetermined spatial area. For example, the optical deflection element thus also changes a beam shape. In other words, a light beam incident on the optical deflection element can be changed by the optical deflection element both in its beam shape and in its direction of propagation.

According to at least one embodiment, the optoelectronic arrangement comprises an evaluation unit. The evaluation unit is advantageously configured to detect a signal and evaluate it electronically. Preferably, the evaluation unit is configured for a two-or three-dimensional distance measurement method.

According to at least one embodiment of the optoelectronic arrangement, the optical deflection element is arranged downstream of the semiconductor body in its main emission direction. In particular, the optical deflection element is arranged such that electromagnetic radiation emitted by the optoelectronic semiconductor body during operation is radiated through the optical deflection element into a larger spatial area.

According to at least one embodiment of the optoelectronic arrangement, the optical deflection element fans the electromagnetic radiation in a lateral direction at a lateral emission angle and in a vertical direction at a vertical emission angle. Preferably, the vertical direction is oriented transversely, in particular perpendicular to the lateral direction. The fanning of the electromagnetic radiation changes, for example, a beam shape of the electromagnetic radiation emitted by the semiconductor body during operation. In particular, the vertical emission angle and the lateral emission angle describe propagation angles along a common propagation direction. Advantageously, a large spatial area can thus be irradiated with electromagnetic radiation.

According to at least one embodiment of the optoelectronic arrangement, the evaluation unit is configured to detect the electromagnetic radiation of the semiconductor body reflected by an object. An object is, for example, a user's face. Advantageously, the optoelectronic arrangement can be used to determine a distance between the object and the optoelectronic arrangement. In particular, the evaluation unit is configured to determine a distance of the object from the semiconductor body.

According to at least one embodiment, the optoelectronic arrangement comprises:
a semiconductor body configured to emit coherent electromagnetic radiation in a main emission direction,
an optical deflection element, and
an evaluation unit, wherein
the optical deflection element is arranged downstream of the semiconductor body in its main emission direction,
the optical deflection element fans out the electromagnetic radiation in a lateral direction at a lateral emission angle and fans it out in a vertical direction at a vertical emission angle, and
the evaluation unit is configured to detect the electromagnetic radiation of the semiconductor body reflected by an object.

The optoelectronic arrangement described here is based on the following considerations, among others: In today's optical sensor systems for detecting the distance of an object, surface emitters, or VCSELs for short (vertical-cavity surface-emitting lasers), are often used as light sources in combination with simple diffractive optical elements. These sensor systems achieve an emission angle of 90° in a vertical direction and 120° in a lateral direction. Furthermore, the optical output power of the surface emitters is limited by their design.

The optoelectronic arrangement described here makes use, among other things, of the idea of combining an edge-emitting semiconductor body with a reflective optical deflection element. The optical deflection element can generate an adjustable luminance in a desired emission angle range. An optical output power can be scaled particularly easily by increasing the number of semiconductor bodies. Another advantage is that particularly large emission angle ranges can be covered.

According to at least one embodiment of the optoelectronic arrangement, the lateral emission angle is greater than 120°, preferably greater than 140°, particularly preferably greater than 160°. In particular, the lateral emission angle is greater than 179°. A large lateral emission angle makes it possible to illuminate a large spatial area. Objects can be detected in the illuminated spatial area.

According to at least one embodiment of the optoelectronic arrangement, the vertical emission angle is greater than 70°, preferably greater than 80°, particularly preferably greater than 90°. A large vertical emission angle makes it possible to illuminate a large spatial area. Objects can be detected in the illuminated spatial area.

According to at least one embodiment of the optoelectronic arrangement, the semiconductor body is an edge-emitting component. In particular, the semiconductor body emits electromagnetic radiation during operation through a side surface which is oriented transversely to a main extension direction of the semiconductor body. The main direction of extension runs transversely, in particular perpendicular to a stacking direction of the semiconductor layers of the semiconductor body. Preferably, two opposing side surfaces of the semiconductor body each form a resonator mirror of the optical resonator.

According to at least one embodiment of the optoelectronic arrangement, the evaluation unit comprises an optical detector and an integrated circuit. The evaluation unit can use the optical detector to detect electromagnetic radiation. For example, the evaluation unit comprises a photodiode, an active pixel sensor or a CCD sensor. Particularly preferably, the evaluation unit comprises a single photon avalanche photodiode. In particular, the evaluation unit is configured to determine a distance of the object from the semiconductor body by means of a time-of-flight method.

According to at least one embodiment of the optoelectronic arrangement, the optical deflection element is a reflective element. Preferably, the optical deflection element has a reflectivity of more than 90% for the electromagnetic radiation emitted by the semiconductor body during operation. A reflective element is characterized in particular by the low-loss deflection of electromagnetic radiation.

According to at least one embodiment of the optoelectronic arrangement, the optical deflection element has a convex surface. The surface of the optical deflection element is convexly curved, in particular for an observer from outside the optical deflection element. For example, the optical deflection element has a surface with different areas, each of which has different convex curvatures.

According to at least one embodiment of the optoelectronic arrangement, the optical deflection element has a surface with at least one kink. For example, the surface of the optical deflection element has the shape of a prism. Advantageously, a kink can be used to achieve a desired distribution of electromagnetic radiation reflected by the optical deflection element.

According to at least one embodiment of the optoelectronic arrangement, the optical deflection element has a surface with concave and convex areas. A mixture of concave and convex areas enables a particularly high degree of design freedom for the distribution of electromagnetic radiation reflected by the optical deflection element.

According to at least one embodiment of the optoelectronic arrangement, the optical deflection element has a free-form surface. In particular, a free-form surface has no rotational symmetry or translation about an optical axis. A mathematical characterization of the free-form surface is therefore complex. Compared to spherical or aspherical surfaces, a free-form surface has significantly more degrees of freedom. Advantageously, the free-form surface can be shaped in such a way that a particularly homogeneous illumination of a spatial area with a particularly high lateral and vertical emission angle is achieved. Alternatively, the optical deflection element could also be shaped in such a way that a large number of individual points can be projected over a large spatial area. With such point projections, for example, three-dimensional shapes can be detected by the evaluation unit in a particularly simple manner.

According to at least one embodiment of the optoelectronic arrangement, the optical deflection element comprises a cladding region formed with at least one of the following materials: glass, aluminum, silver. For example, the cladding region has a dielectric coating. The dielectric coating advantageously comprises a plurality of alternating layers of a dielectric material whose refractive index varies. In particular, the cladding region describes a region of the optical deflection element that is directly illuminated by the electromagnetic radiation of the semiconductor body. Advantageously, the material of the cladding region has a particularly high optical reflectivity for the electromagnetic radiation emitted by the semiconductor body during operation.

According to at least one embodiment of the optoelectronic arrangement, the optical deflection element comprises a volume region formed with at least one of the following materials: glass, metal, silicon, sapphire, quartz. Preferably, the volume region is formed with a borosilicate glass, steel or aluminum. In particular, the volume region forms a region of the optical deflection element that is at least partially surrounded by the cladding region. Advantageously, the volume region gives the optical deflection element its mechanical stability and is particularly suitable for generating a desired surface shape.

According to at least one embodiment of the optoelectronic arrangement, the optical deflection element comprises a bottom portion formed with at least one of the following materials: glass, gold, tin. In particular, the bottom portion is formed with a gold-tin alloy. The bottom portion is a region of the optical deflection element by which the optical deflection element is attached to a further structure. Advantageously, the bottom portion is therefore particularly easy to connect to another structure. The material of the bottom portion is particularly suitable for producing a bonded connection.

According to at least one embodiment of the optoelectronic arrangement, the optoelectronic arrangement comprises at least two semiconductor bodies. With several semiconductor bodies, an optical output power of the optoelectronic arrangement can be increased particularly easily. In particular, all semiconductor bodies have a different main emission wavelength. Here and in the following, a main emission wavelength describes a wavelength at which an emission spectrum has a global intensity maximum. For example, the main wavelengths of all semiconductor bodies of an optoelectronic arrangement have a difference in the main emission wavelength of less than 10 nm, preferably of less than 5 nm and particularly preferably of less than 2 nm.

According to at least one embodiment of the optoelectronic arrangement, the semiconductor bodies are arranged on opposite sides of the optical deflection element. An arrangement of semiconductor bodies on opposite sides of the optical deflection element makes it possible to increase the lateral and/or vertical emission angle by superimposing the electromagnetic radiation emitted by the semiconductor bodies.

According to at least one embodiment of the optoelectronic arrangement, the optoelectronic arrangement comprises at least four semiconductor bodies. Four semiconductor bodies can be arranged opposite each other around the optical deflection element. Advantageously, this results in particularly homogeneous illumination of a spatial area by the optoelectronic arrangement with a particularly large lateral and/or vertical emission angle. Alternatively, this can also enable a large number of individual points to be projected into a spatial area.

A method for producing an optoelectronic arrangement is further disclosed. The optoelectronic arrangement can be manufactured in particular by means of the method described herein. This means that all features disclosed in connection with the optoelectronic arrangement are also disclosed for the method for producing an optoelectronic arrangement and vice versa.

According to at least one embodiment of the method for producing an optoelectronic arrangement, a semiconductor body an optical deflection element and an evaluation unit are provided.

According to at least one embodiment of the method for producing an optoelectronic arrangement, a curvature of a surface of the optical deflection element is determined in such a way that a desired illumination of the evaluation unit is achieved. For example, the curvature of the surface of the deflection element is determined, inter alia, on the basis of a number of semiconductor bodies used, an arrangement of the semiconductor bodies and the evaluation unit, a lateral emission angle and a vertical emission angle.

According to at least one embodiment of the method for producing an optoelectronic arrangement, the method comprises the following steps:
Providing a semiconductor body an optical deflection element and an evaluation unit,
Determining a curvature of a surface of the optical deflection element in such a way that a desired illumination of the evaluation unit is achieved.

According to at least one embodiment of the method for producing an optoelectronic arrangement, the surface of the optical deflection element is created using a free-form simulation tool. In particular, the surface is created by the free-form simulation tool on the basis of at least one of the following parameters: lateral emission angle, vertical emission angle, arrangement of the semiconductor bodies, distances between the semiconductor bodies and radiation characteristics of the semiconductor bodies. The radiation characteristics of the semiconductor bodies include, in particular, a main emission wavelength, a line width, a pulse length, a beam diameter and a beam divergence.

An optoelectronic arrangement described here is particularly suitable for use in optical sensor systems, for example for 2D gesture recognition, a 3D sensor application, for example driver monitoring in a vehicle. Preferably, the optoelectronic arrangement can be used for passenger detection, environment monitoring, environment measurement, intrusion detection, accident detection or interior monitoring.

Further advantages and advantageous configurations and further embodiments of the optoelectronic arrangement result from the following description in connection with the exemplary embodiments shown in the figures.

### BRIEF DESCRIPTION OF THE DRAWINGS

FIGS. 1A and 1B show a schematic sectional view and a schematic plan view of an optoelectronic arrangement described herein according to a first exemplary embodiment,

FIGS. 2A, 2B and 2C schematic sectional views and a schematic plan view of an optoelectronic arrangement described herein according to a second exemplary embodiment,

FIG. 3 a schematic top view of an optoelectronic arrangement described here according to a third exemplary embodiment,

FIG. 4 a schematic top view of an optoelectronic arrangement described here according to a fourth exemplary embodiment,

FIG. 5 a schematic sectional view of an optical deflection element described here according to a first exemplary embodiment,

FIGS. 6A and 6B show a schematic sectional view and a schematic top view of an optical deflection element described herein according to a second exemplary embodiment,

FIGS. 7A and 7B show a schematic sectional view and a schematic top view of an optical deflection element as described herein according to a third exemplary embodiment,

FIGS. 8A and 8B show a schematic sectional view and a schematic plan view of an optical deflection element described herein according to a fourth exemplary embodiment,

FIGS. 9A and 9B show a schematic sectional view and a schematic plan view of an optical deflection element described herein according to a fifth exemplary embodiment,

FIGS. 10A and 10B show a schematic sectional view and a schematic plan view of an optical deflection element described herein according to a sixth exemplary embodiment,

FIGS. 11A and 11B show a schematic sectional view and a schematic top view of an optical deflection element described herein according to a seventh exemplary embodiment,

FIG. 12 a schematic sectional view of an optoelectronic arrangement described here according to a fifth exemplary embodiment,

FIG. 13 a simulated illumination on the evaluation unit from the optoelectronic arrangement according to the fifth exemplary embodiment, and

FIG. 14 a simulated illumination on the evaluation unit from the optoelectronic arrangement according to the third exemplary embodiment.

### DETAILED DESCRIPTION

Elements that are identical, similar or have the same effect are marked with the same reference symbols in the figures. The figures and the proportions of the elements shown in the figures should not be considered to be to scale. Rather, individual elements may be shown in exaggerated size for better visualization and/or better comprehensibility.

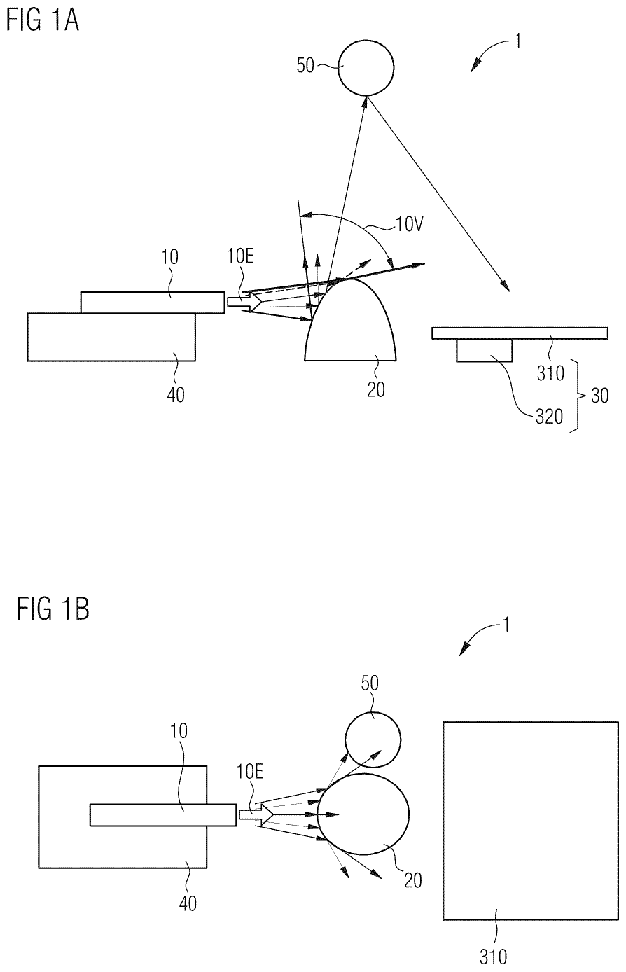

FIGS. 1A and 1B show a schematic sectional view and a schematic plan view of an optoelectronic arrangement 1 described herein according to a first exemplary embodiment.

FIG. 1A shows a schematic sectional view of the optoelectronic arrangement 1 according to the first exemplary embodiment. The optoelectronic arrangement 1 comprises a semiconductor body 10 which is arranged to emit coherent radiation in a main emission direction 10E, an optical deflection element 20 and an evaluation unit 30.

The semiconductor body 10 is arranged on a mounting body 40. For example, the mounting body 40 is arranged to dissipate heat from the semiconductor body 10. In particular, the mounting body 40 is formed with a ceramic material. Furthermore, the semiconductor body 10 comprises an optically active region which is configured to emit electromagnetic radiation. Preferably, the optically active region has a p-n junction, a double heterostructure, a single quantum well structure (SQW) or a multi-quantum well structure (MQW) for the generation of radiation.

The semiconductor body 10 is an edge-emitting laser diode. In particular, an optical resonator is formed in the semiconductor body along a resonator axis 10R. The optical resonator enables a circulation of electromagnetic radiation along the resonator axis 10R and favors a stimulated emission of electromagnetic radiation. Advantageously, the optical resonator enables coherent emission of electromagnetic radiation. The main emission direction 10E runs parallel and in particular coaxial to the resonator axis 10R.

The optical deflection element 20 has a convex surface. The optical deflection element 20 is configured to change the direction of propagation of electromagnetic radiation. Preferably, the optical deflection element 20 serves to radiate electromagnetic radiation into a predetermined spatial area. The optical deflection element 20 is arranged downstream of the semiconductor body 10 in its main emission direction 10E. In particular, the optical deflection element 20 is arranged such that electromagnetic radiation emitted by the optoelectronic semiconductor body 10 during operation is radiated into a larger spatial area by the optical deflection element 20. The optical deflection element 20 is a reflective element that has a high reflectivity for the electromagnetic radiation emitted by the semiconductor body 10 during operation. In particular, the optical deflection element 20 has a reflectivity of at least 90%, preferably of at least 95% and particularly preferably of at least 99% for the electromagnetic radiation emitted by the semiconductor body 10 during operation.

The optical deflection element 20 fans the electromagnetic radiation in a vertical direction at a vertical emission angle 10V. The fanning out of the electromagnetic radiation changes in particular a beam shape of the electromagnetic radiation emitted by the semiconductor body 10 during operation. Advantageously, a large spatial area can thus be irradiated with electromagnetic radiation.

The vertical emission angle 10V is greater than 70°, preferably greater than 80°, particularly preferably greater than 90°. A large vertical emission angle 10V makes it possible to illuminate a large spatial area in which objects 50 can be detected.

The evaluation unit 30 is configured to detect an optical signal and evaluate it electronically. A main extension plane of the evaluation unit 30 is preferably aligned parallel to a main extension plane of the semiconductor body 10. The evaluation unit 30 is further configured to detect the electromagnetic radiation of the semiconductor body 10 reflected by an object 50. In particular, the evaluation unit 30 is configured to determine a distance of the object 50 from the semiconductor body 10. An object 50 is, for example, a user's face. Advantageously, the optoelectronic arrangement 1 can be used to determine a distance between the object 50 and the optoelectronic arrangement 1.

The evaluation unit 30 comprises an optical detector 310 and an integrated circuit 320. With the optical detector 310, the evaluation unit 30 can detect electromagnetic radiation. The integrated circuit 320 is preferably arranged on a side of the detector 310 facing away from the object 50. Advantageously, the detector 310 is not shadowed by the integrated circuit 320.

For example, the evaluation unit 30 comprises a photodiode, an active pixel sensor or a CCD sensor. Particularly preferably, the evaluation unit 30 comprises a single photon avalanche photodiode. In particular, the evaluation unit 30 is configured to determine a distance of the object 50 from the semiconductor body 10 by means of a time-of-flight method.

FIG. 1B shows a schematic top view of an optoelectronic semiconductor component 1 according to the first exemplary embodiment. In FIG. 1B, it is clearly recognizable that the main extension plane of the optical detector 310 extends along the main extension plane of the semiconductor body 10. Furthermore, it can be seen that the optical deflection element 20 also has a convex surface in the top view.

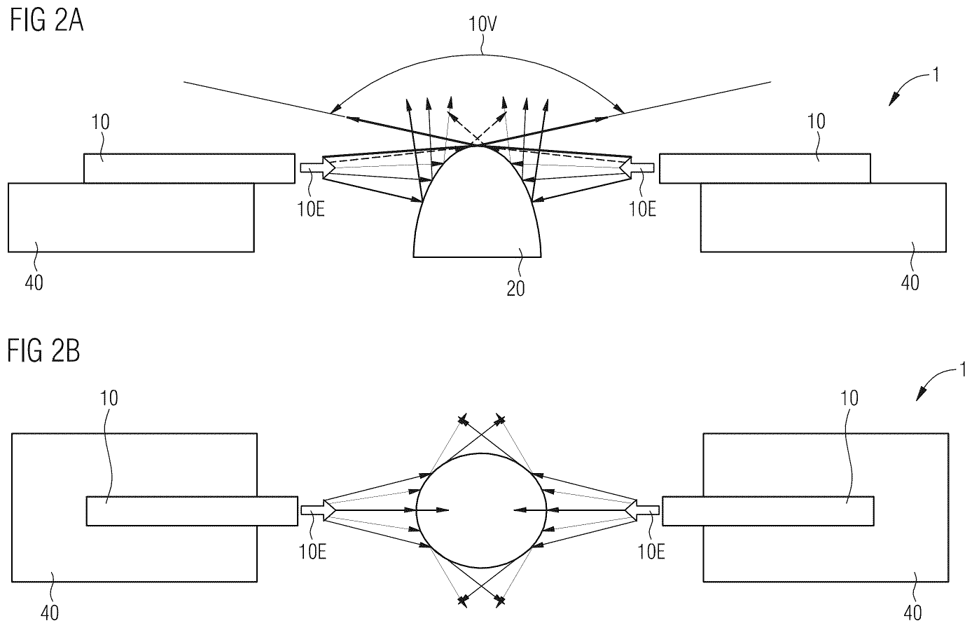

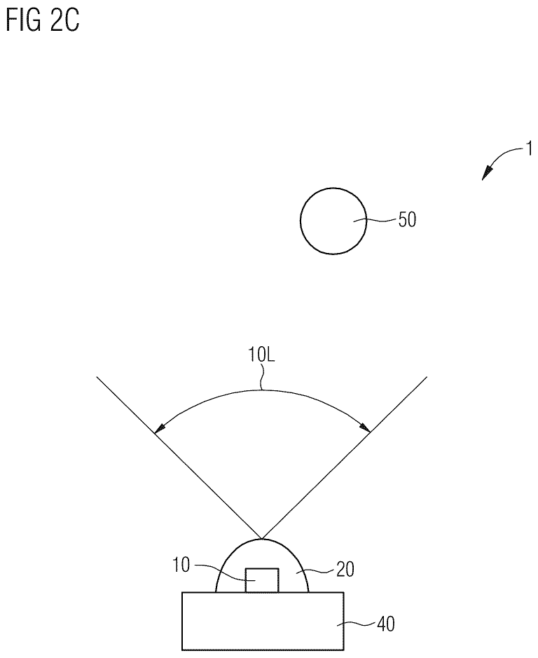

FIGS. 2A, 2B and 2C show schematic sectional views and a schematic top view of an optoelectronic arrangement 1 described herein according to a second exemplary embodiment. The second exemplary embodiment essentially corresponds to the first exemplary embodiment shown in FIGS. 1A and 1B. Here and in the following figures, an evaluation unit 30 is not explicitly shown for reasons of clarity.

FIGS. 2A and 2B clearly show that the optoelectronic arrangement 1 according to the second exemplary embodiment comprises two semiconductor bodies 10. The semiconductor bodies 10 are arranged on opposite sides of a common optical deflection element 20. Both semiconductor bodies 10 are arranged in a common plane. The main emission directions 10E of the semiconductor bodies 10 are oriented parallel, in particular coaxially, to each other. The main emission directions 10E of the semiconductor bodies 10 are preferably oriented in opposite directions to one another.

An arrangement of the semiconductor bodies 10 on opposite sides of the optical deflection element 20 makes it possible to increase the vertical emission angle 10V and/or the lateral emission angle 10L by superimposing the electromagnetic radiation emitted by the two semiconductor bodies 10.

FIG. 2C shows a further schematic sectional view, which is rotated by 90° compared to the sectional view in FIG. 2A. In the sectional view of FIG. 2C, it can be seen that the optical deflection element 20 fans out the electromagnetic radiation in a lateral direction at a lateral emission angle 10L. The lateral emission angle 10L is greater than 120°, preferably greater than 140°, particularly preferably greater than 160°. In particular, the lateral emission angle 10L is greater than 179°. A large lateral emission angle 10L makes it possible to illuminate a large spatial area. Objects 50 can be detected in the illuminated spatial area.

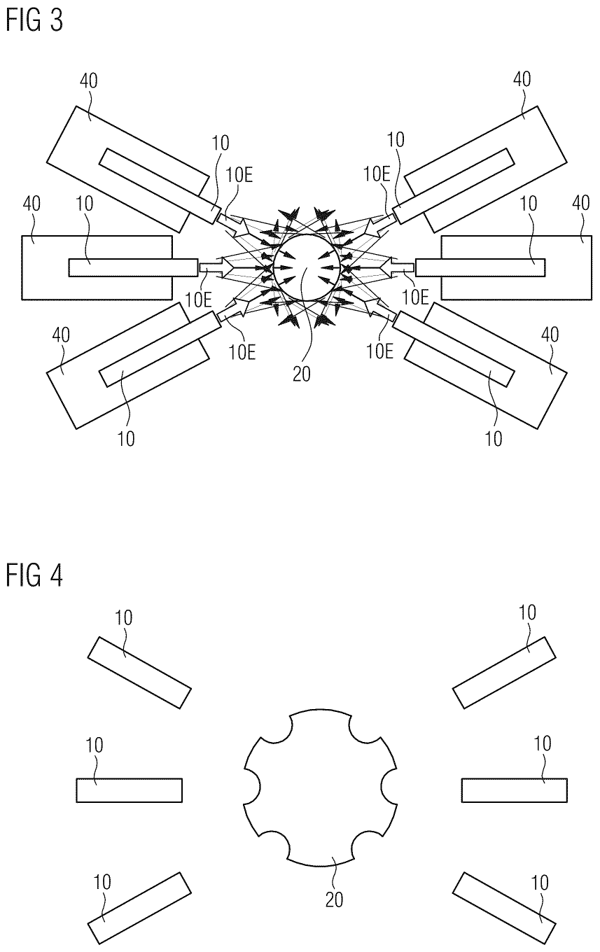

FIG. 3 shows a schematic top view of an optoelectronic arrangement 1 described here according to a third exemplary embodiment. The third exemplary embodiment essentially corresponds to the first exemplary embodiment shown in FIGS. 1A and 1B. In contrast to the first exemplary embodiment, the optoelectronic arrangement 1 according to the third exemplary embodiment comprises six semiconductor bodies 10. In each case, two semiconductor bodies 10 are arranged in such a way that their main emission directions 10E are directed in opposite directions. All semiconductor bodies 10 are arranged in a common plane. In this way, a particularly large spatial area can be illuminated advantageously. In addition, a higher optical output power can be achieved particularly easily by increasing the number of semiconductor bodies 10.

FIG. 4 shows a schematic top view of an optoelectronic arrangement 1 described here according to a fourth exemplary embodiment. The fourth exemplary embodiment essentially corresponds to the third exemplary embodiment shown in FIG. 3. In contrast to the third exemplary embodiment, the optoelectronic arrangement 1 according to the fourth exemplary embodiment comprises an optical deflection element 20 with a surface having convex and concave areas. A particularly homogeneous illumination of a spatial area by the optoelectronic arrangement 1 can be achieved by a suitable selection of the surface contour of the optical deflection element 20 and a corresponding alignment of the semiconductor bodies 10. Alternatively, it is also possible to project a large number of individual points into the spatial area.

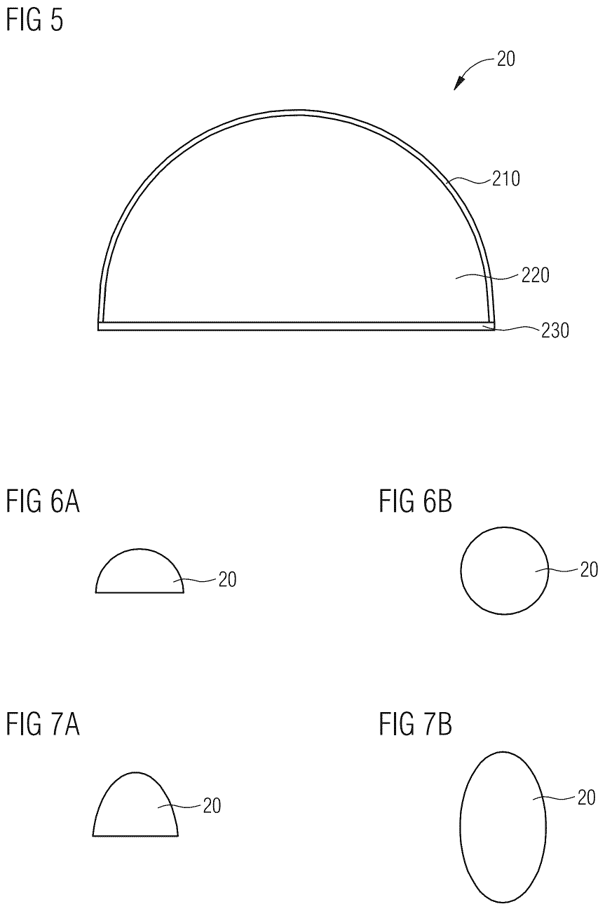

FIG. 5 shows a schematic sectional view of an optical deflection element 20 described herein according to a first exemplary embodiment. The optical deflection element 20 comprises a cladding region 210, a volume region 220 and a bottom portion 230.

The cladding region 210 is formed with at least one of the following materials: Glass, aluminum, silver. For example, the cladding region 210 comprises a dielectric coating. The dielectric coating advantageously comprises a plurality of alternating layers of a dielectric material whose refractive index varies. In particular, the cladding region 210 describes a region of the optical deflection element 20 that is directly illuminated by the electromagnetic radiation of the semiconductor body 10. Advantageously, the material of the cladding region 210 has a particularly high optical reflectivity for the electromagnetic radiation emitted by the semiconductor body 10 during operation. For example, the cladding region 210 has a reflectivity of at least 90%, preferably of at least 95% and particularly preferably of at least 99% for the electromagnetic radiation emitted by the semiconductor body 10 during operation.

The volume region 220 is formed with at least one of the following materials: Glass, metal, silicon, sapphire, quartz. Preferably, the volume region 220 is formed with a borosilicate glass, steel or aluminum. In particular, the volume region 220 forms a region of the optical deflection element 20 that is at least partially surrounded by the cladding region 210. Advantageously, the volume region 220 gives the optical deflection element 20 its mechanical stability and is particularly well suited for generating a desired surface shape.

The bottom portion 230 is formed with at least one of the following materials: Glass, gold, tin. In particular, the bottom portion 230 is formed with a gold-tin alloy. The bottom portion 230 is a region of the optical deflection element 20 to which the optical deflection element 20 is attached to a further structure. Advantageously, the bottom portion 230 is therefore particularly easy to connect to a further structure. The material of the bottom portion 230 is particularly suitable for producing a bonded connection.

FIGS. 6A and 6B show a schematic sectional view and a schematic top view of an optical deflection element 20 described herein according to a second exemplary embodiment. The optical deflection element 20 has a convex surface in the form of a hemisphere.

FIGS. 7A and 7B show a schematic sectional view and a schematic top view of an optical deflection element 20 described herein according to a third exemplary embodiment. The optical deflection element 20 has a convex surface in the form of an ellipsoid.

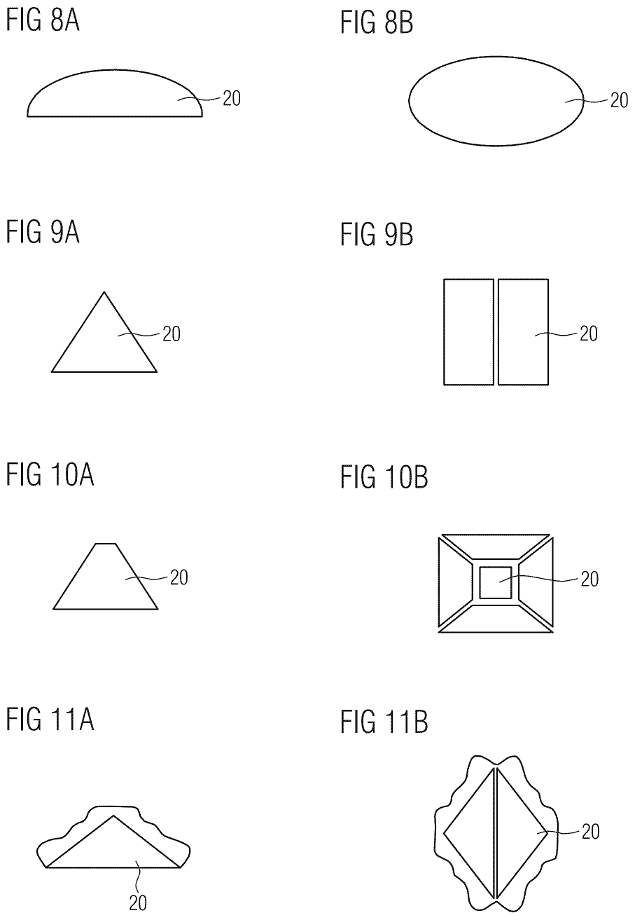

FIGS. 8a and 8b show a schematic sectional view and a schematic top view of an optical deflection element 20 described herein according to a fourth exemplary embodiment. The optical deflection element 20 has a convex surface in the form of an ellipsoid.

FIGS. 9A and 9B show a schematic sectional view and a schematic top view of an optical deflection element 20 described herein according to a fifth exemplary embodiment. The optical deflection element 20 has a convex surface with a kink. The surface of the optical deflection element 20 has the shape of a three-sided prism.

FIGS. 10A and 10B show a schematic sectional view and a schematic top view of an optical deflection element 20 described herein according to a sixth embodiment. The optical deflection element 20 has a convex surface with several kinks. The surface of the optical deflection element 20 has the shape of a truncated pyramid of a four-sided pyramid.

FIGS. 11A and 11B show a schematic sectional view and a schematic top view of an optical deflection element 20 described herein according to a seventh exemplary embodiment. The optical deflection element 20 has a surface with convex and concave partial regions. The surface of the optical deflection element 20 is a free-form surface.

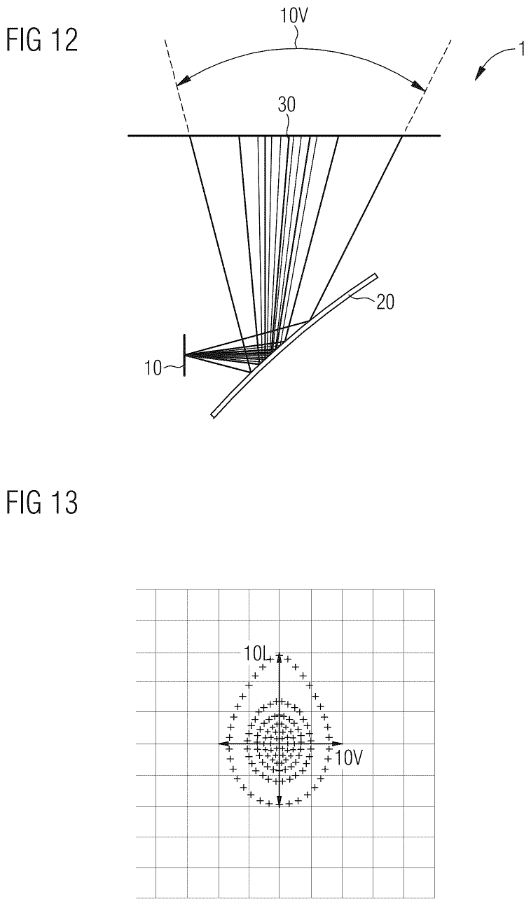

FIG. 12 shows a schematic sectional view of the optoelectronic arrangement 1 according to the fifth exemplary embodiment. The fifth exemplary embodiment essentially corresponds to the first exemplary embodiment shown in FIGS. 1A and 1B. FIG. 12 shows a fanning out of the electromagnetic radiation emitted by the semiconductor body 10 during operation into a vertical emission angle 10V by the optical deflection element 20. Only a section of the surface of the optical deflection element 20 is shown.

FIG. 13 shows a simulated illumination on the evaluation unit from the optoelectronic arrangement according to the fifth exemplary embodiment. In the simulated illumination after reflection of the electromagnetic radiation at the optical deflection element 20, an expansion of the vertical emission angle 10V and the lateral emission angle 10L can be seen. The expansion of the vertical emission angle 10V is greater than the expansion of the lateral emission angle 10L.

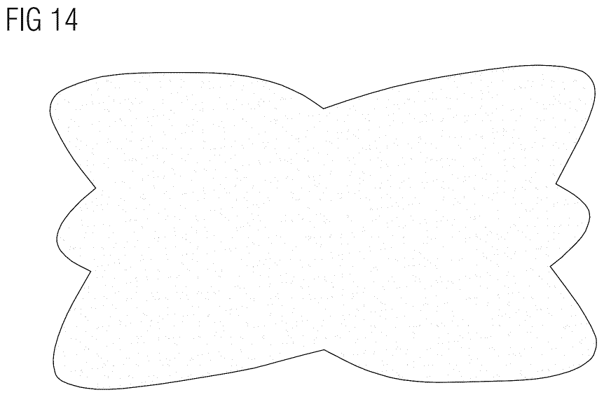

FIG. 14 shows a simulated illumination on the evaluation unit from the optoelectronic arrangement according to the third exemplary embodiment. The illumination shown in FIG. 14 can be generated, for example, by superimposing the electromagnetic radiation of six semiconductor bodies 10, which are arranged around an optical deflection element 20 according to the third exemplary embodiment in FIG. 3. This advantageously results in an almost rectangular and particularly homogeneous illumination of a spatial area.

The invention is not limited by the description based on the exemplary embodiments. Rather, the invention includes any new feature as well as any combination of features, which includes in particular any combination of features in the patent claims, even if this feature or combination itself is not explicitly stated in the patent claims or exemplary embodiments.

1. An optoelectronic arrangement comprising:
a semiconductor body configured to emit a coherent electromagnetic radiation in a main emission direction,
an optical deflection element, and
an evaluation unit wherein
the optical deflection element is arranged downstream of the semiconductor body in its main emission direction,
the optical deflection element fans out the electromagnetic radiation in a lateral direction at a lateral emission angle and fans it out in a vertical direction at a vertical emission angle,
the evaluation unit is configured to detect the electromagnetic radiation of the semiconductor body reflected by an object, and
the semiconductor body is an edge-emitting component.

2. The optoelectronic arrangement according to claim 1, in which the lateral emission angle is greater than 120°, preferably greater than 140°, particularly preferably greater than 160°.

3. The optoelectronic arrangement according to claim 1, wherein the vertical emission angle is greater than 70°, preferably greater than 80°, particularly preferably greater than 90°.

4. The optoelectronic arrangement according to claim 1, wherein the semiconductor body emits, in operation, electromagnetic radiation through a side surface which is oriented transversely to a main extension direction of the semiconductor body.

5. The optoelectronic arrangement according to claim 1, wherein the evaluation unit comprises an optical detector and an integrated circuit.

6. The optoelectronic arrangement according to claim 1, wherein the optical deflection element is a reflective element.

7. The optoelectronic arrangement according to claim 1, wherein the optical deflection element has a convex surface.

8. The optoelectronic arrangement according to claim 1, wherein the optical deflection element has a surface with at least one kink.

9. The optoelectronic arrangement according to claim 1, wherein the optical deflection element has a surface with concave and convex regions.

10. The optoelectronic arrangement according to claim 1, wherein the optical deflection element has a free-form surface.

11. The optoelectronic arrangement according to claim 1, wherein the optical deflection element comprises a cladding region formed with at least one of the following materials: glass, dielectric, aluminum, silver.

12. The optoelectronic arrangement according to claim 1, wherein the optical deflection element comprises a volume region formed with at least one of the following materials: glass, metal, silicon, sapphire, quartz.

13. The optoelectronic arrangement according to claim 1, wherein the optical deflection element comprises a bottom portion formed with at least one of the following materials: glass, gold, tin.

14. The optoelectronic arrangement according to claim 1, wherein the optoelectronic arrangement comprises at least two semiconductor bodies.

15. The optoelectronic arrangement according to claim 1, wherein the semiconductor bodies are arranged on opposite sides of the optical deflection element.

16. The optoelectronic arrangement according to claim 1, wherein the optoelectronic arrangement comprises at least four semiconductor bodies.

17. A method for producing an optoelectronic arrangement comprising:
providing an edge-emitting semiconductor body an optical deflection element and an evaluation unit, and
determining a curvature of a surface of the optical deflection element in such a way that a desired illumination of the evaluation unit is achieved.

18. The method for producing an optoelectronic arrangement according to claim 1, wherein the surface of the optical deflection element is created using a free-form simulation tool.

19. The optoelectronic arrangement according to claim 12, wherein the optical deflection element comprising the volume region is formed with borosilicate, steel, or aluminum.

20. The optoelectronic arrangement according to claim 13, wherein the optical deflection element comprises a bottom portion formed of gold-tin.
